(19) United States
(12) Patent Application Publication
(10) Pub. No.: US 2012/0319562 A1
(43) Pub. Date: Dec. 20, 2012

(54) LED PACKAGE AND MANUFACTURING METHOD THEREOF

(75) Inventor: Seung Hyun RA, Gyeonggi-do (KR)

(73) Assignee: SAMSUNG Electro-Mechanics Co., Ltd.

(21) Appl. No.: 13/460,445

(22) Filed: Apr. 30, 2012

(30) Foreign Application Priority Data
Jun. 15, 2011 (KR) 10-2011-0058129

(51) Int. Cl. H01J 1/62; H05K 3/30; B82Y 99/00

(52) U.S. Cl. 313/498; 29/832; 977/932

(57) ABSTRACT

Disclosed herein a light emitting diode package including: a package body with an opening portion; a light emitting diode chip mounted on the bottom of the opening portion; and a sheet installed on the top of the opening portion and including an anti-reflecting unit formed in a moth-eye pattern, which can increase light emitting efficiency.

### CROSS REFERENCE(S) TO RELATED APPLICATIONS

This application claims the benefit under 35 U.S.C. Section 119 of Korean Patent Application Serial No. 10-2011-0058129, entitled “LED Package and Manufacturing Method Thereof” filed on Jun. 15, 2011, which is hereby incorporated by reference in its entirety into this application.

### BACKGROUND OF THE INVENTION

1. Technical Field

The present invention relates to an LED package and a manufacturing method thereof, and more particularly, to an LED package and a manufacturing method that can improve light emitting efficiency by reducing reflection of light on an interface.

2. Description of the Related Art

In general, since a light emitting diode (LED) as a semiconductor device converting electrical energy into optical energy is excellent in optical efficiency and can be miniaturized, the LED is widely used in various display apparatuses mainly as a package type. In particular, the LED is actively developed as a high-efficiency and high-power light source that can replace a backlight of a lighting apparatus and the display apparatus.

FIG. 1 is a cross-sectional view of a light emitting diode package in the related art.

As shown in FIG. 1, a light emitting diode package 10 includes a package body 11, a light emitting diode chip 12 mounted in a concave portion 11a of the package body 11, lead frames 13 and 14 for electrical connection with other components, and an encapsulant 15 formed to cover the light emitting diode chip 12 in the concave portion 11a of the package body 11 and one or more fluorescent particles are contained in the encapsulant 15.

Therefore, the light emitting diode package in the related art emits light generated from the light emitting diode chip 12 to the outside through the fluorescent particles of the encapsulant.

However, when the light generated from the light emitting diode chip passes through the encapsulant containing the fluorescent particles, light permeability is reduced, such that light emitting efficiency of the light emitting diode package deteriorates.

### SUMMARY OF THE INVENTION

An object of the present invention is to provide a light emitting diode package and a manufacturing method thereof that can improve light emitting efficiency of the light emitting diode package by implementing a sheet that can serve to prevent reflection of light as well as emit light absorbed from a light emitting diode chip to the outside.

According to an exemplary embodiment of the present invention, there is provided a light emitting diode package including: a package body with an opening portion; a light emitting diode chip mounted on the bottom of the opening portion; and a sheet installed on the top of the opening portion and including an anti-reflecting unit formed in a moth-eye pattern.

In this case, the moth-eye pattern may have a plurality of protrusions and the plurality of protrusions may have a cone shape.

Further, the moth-eye pattern may be formed in a nano size.

In addition, the sheet may be made of a silicon material and the sheet may be a fluorescent sheet containing fluorescent particles.

A predetermined medium may be received between the light emitting diode chip and the sheet and the predetermined medium may be configured by air or silicon.

In the package body, a side wall may be formed on the circumference of the opening portion and the side wall may be inclined toward the top from the bottom.

The side wall may be applied with a metal thin film to reflect light emitted from the light emitting diode chip.

The anti-reflecting unit may be formed on one surface or both surfaces of the sheet and the sheet may have the anti-reflecting unit formed in the moth-eye pattern by using an imprint method through a stamp.

The light emitting diode package may further include a convex lens covering the opening portion and may further include first and second lead frames mounted on the package body to expose the bottom of the opening portion, and the light emitting diode chip may be electrically connected to each of the first and second lead frames.

Meanwhile, according to another exemplary embodiment of the present invention, there is provided a manufacturing method of a light emitting diode package including: mounting a light emitting diode chip on the bottom of an opening portion of a package body; fabricating a sheet with an anti-reflecting unit formed in a moth-eye pattern; and installing the sheet on the top of the opening portion.

Herein, in the fabricating of the sheet, the sheet with the anti-reflecting unit formed in the moth-eye pattern may be fabricated by using an imprint method through a stamp.

In addition, the moth-eye pattern may have a plurality of protrusions and the plurality of protrusions may have a cone shape.

Moreover, the anti-reflecting unit may be formed on one surface or both surfaces of the sheet.

Further, the fabricating of the sheet may include: applying a resin layer to the sheet; forming the anti-reflecting unit formed in the moth-eye pattern on the resin layer; and hardening the resin layer with the anti-reflecting unit formed in the moth-eye pattern.

Besides, the manufacturing method may further include covering the opening portion with a convex lens.

### BRIEF DESCRIPTION OF THE DRAWINGS

FIG. 1 is a cross-sectional view of a light emitting diode package in the related art.

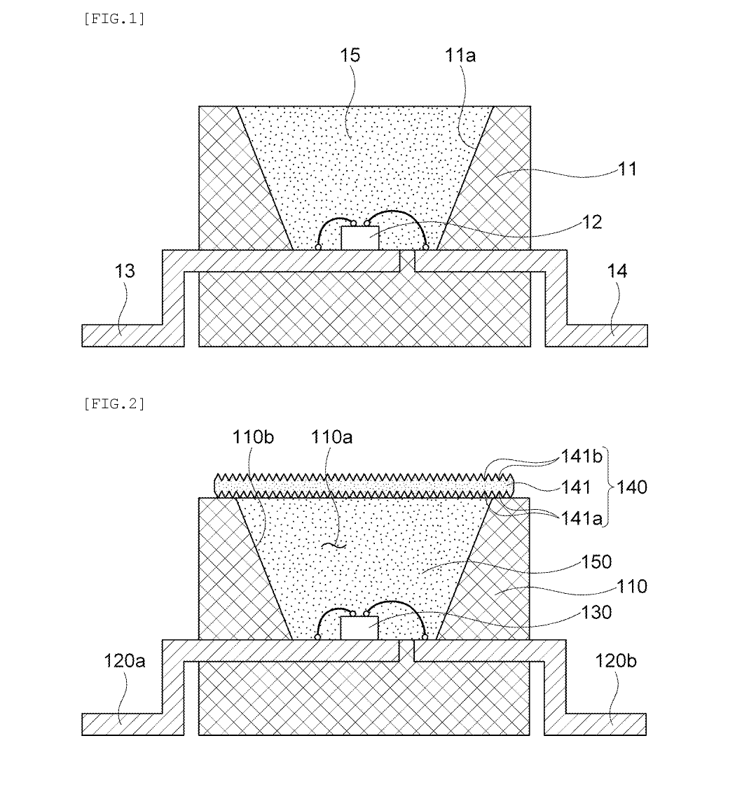

FIG. 2 is a cross-sectional view of a light emitting diode package according to an exemplary embodiment of the present invention.

FIG. 3 is a cross-sectional view of a light emitting diode package according to another exemplary embodiment of the present invention.

FIGS. 4 to 8 are cross-sectional views showing a manufacturing method of a light emitting diode package according to an exemplary embodiment of the present invention.

### DESCRIPTION OF THE PREFERRED EMBODIMENTS

Terms or words used in the specification and the appended claims should not be construed as normal and dictionary meanings and should be construed as meanings and concepts which conform with the spirit of the present invention according to a principle that the inventor can properly define the concepts of the terms in order to describe his/her own invention in the best way.

Accordingly, embodiments disclosed in the specification and configurations shown in the accompanying drawings are just the most preferred embodiment, but are not limited to the spirit and scope of the present invention. Therefore, at this application time, it will be appreciated that various equivalents and modifications may be included within the spirit and scope of the present invention.

Hereinafter, exemplary embodiments of the present invention will be described in detail with reference to the accompanying drawings.

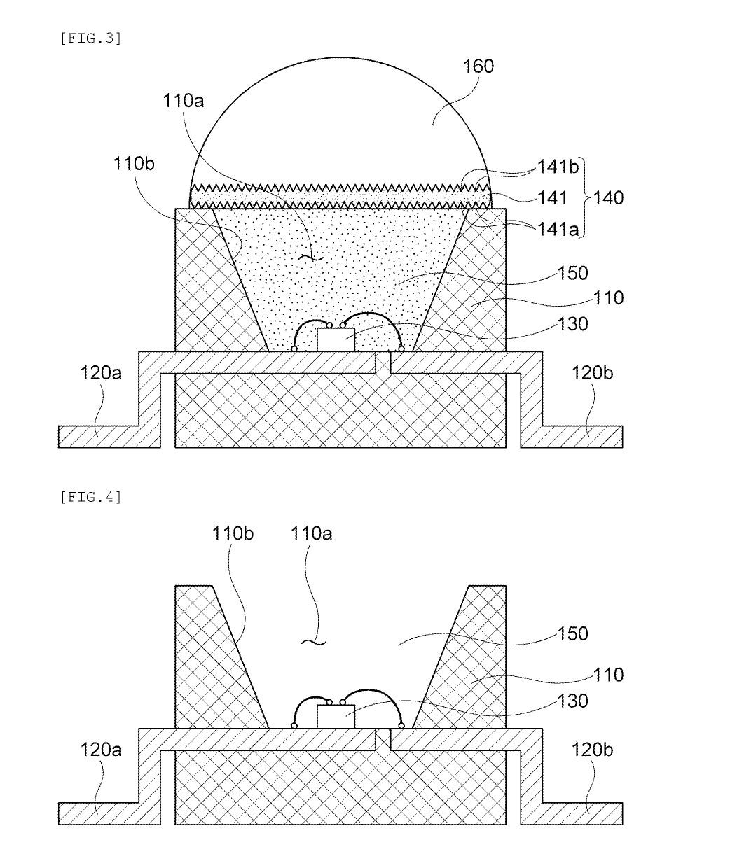

FIG. 2 is a cross-sectional view of a light emitting diode package according to an exemplary embodiment of the present invention.

As shown in FIG. 2, a light emitting diode package includes a package body 110, first and second lead frames 120a and 120b, a light emitting diode chip 130, and a sheet 140.

The package body 110 is formed by molding a synthetic resin such as a molding epoxy resin and the first and second lead frames 120a and 120b are mounted on the package body 110 for electrical connection with other components.

In addition, an opening portion 110a for mounting the light emitting diode chip 130 is formed in the package body 110 and a side wall 110b is formed on the circumference of the opening portion 110a. Herein, the opening portion 110a has the side wall 110b which is inclined toward the top from the bottom in order to guide the light emitted from the light emitting diode chip 130 toward the top.

Further, the side wall 110b may be applied with a metal thin film such as Al, and the like to absorb the light emitted from the light emitting diode chip 130 and reflect the light without a loss.

The light emitting diode chip 130 is electrically mounted and fixed onto the first lead frame 120a positioned on the bottom of the opening portion 110a. Further, the light emitting diode chip 130 is electrically connected with the second lead frame 120b through a wire and when current is applied to the light emitting diode chip 130 from the outside, the light emitting diode chip 130 serves to emit light to generate light.

The sheet 140 is installed on the top of the opening portion 110a and has an anti-reflecting unit 141 of which both surfaces (the top and the bottom) are formed in moth-eye patterns 141a and 141b in order to improve light permeability.

Herein, the moth-eye patterns 141a and 141b may be formed by a plurality of protrusions having a nano size and the plurality of protrusions may have a cone shape.

In addition, the moth-eye patterns 141a and 141b have a nano structure (for example, a structure of 200 nm or less) of tens nanometers to hundreds nanometers or micrometers scale to reduce reflectivity on an interface.

The moth-eye effect is more effective in a pattern of a size smaller than a wavelength range of light reflectivity on the interface is rapidly reduced by consecutively changing refractivity of light incident in and the moth-eye pattern, that is, the plurality of protrusions having the nano size to remarkably improve light permeability.

Meanwhile, the sheet 140 may be formed by the fluorescent sheet manufactured by using a fluorescent substance as a main component, more specifically, may be manufactured by using a silicon material containing the fluorescent particles.

In addition, the sheet 140 with the anti-reflecting unit 141 formed in the moth-eye patterns 141a and 141b may be manufactured by using an imprint method through a stamp.

More specifically, a resin layer 141_1 is applied to the sheet 140 and thereafter, the moth-eye patterns 141a and 141b are formed on the resin layer 141_1 by using the imprint method, and is hardened to manufacture the sheet 140 with the anti-reflecting unit 141.

As such, by minimizing the reflectivity of light and increasing light permeability through the anti-reflecting unit 141 formed on the sheet 140, light emitting performance of the light emitting diode package can be significantly improved.

In addition, in FIG. 2, the anti-reflecting unit 141 of which both surfaces of the sheet 140 are formed by the moth-eye patterns 141a and 141b is disclosed, but is not limited thereto and the anti-reflecting unit 141 in which one surface (the top or the bottom) of the sheet 140 is formed by the moth-eye pattern may be formed.

In the light emitting diode package according to the present invention, a predetermined medium 150 is received in the opening portion 110a between the light emitting diode chip 130 and the sheet 140. The medium 150 may be configured by air or silicon.

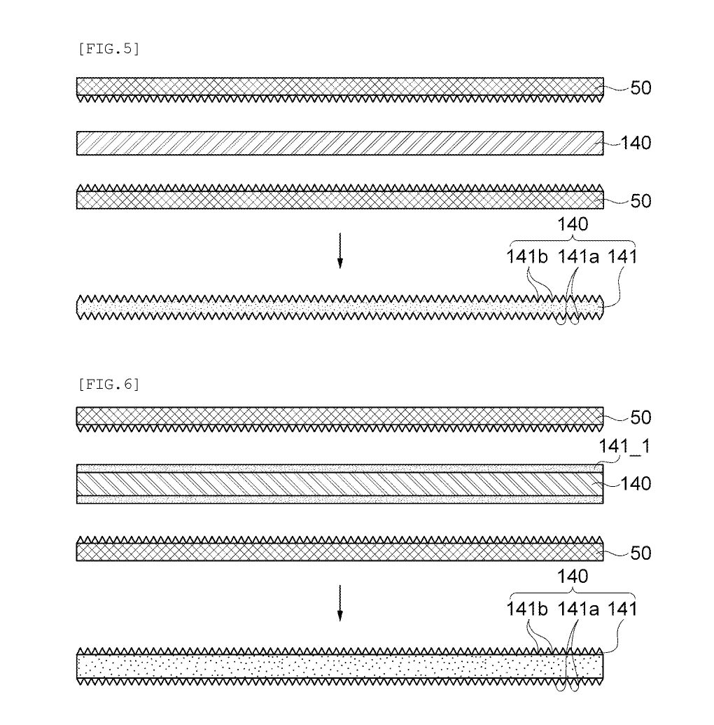

FIG. 3 is a cross-sectional view of a light emitting diode package according to another exemplary embodiment of the present invention and as shown in FIG. 3, a light emitting diode package further includes a package body 110, first and second lead frames 120a and 120b, a light emitting diode chip 130, a sheet 140, and a lens 160.

The lens 160 is formed by a convex lens covering the opening portion 110a and is used to increase the light emitting efficiency of the light emitting diode chip 130.

In addition, since configurations and operations of the package body 110, the first and second lead frames 120a and 120b, the light emitting diode chip 130, and the sheet 140 are the same as each other as shown in FIG. 2, a detailed description will be omitted.

Hereinafter, a manufacturing process of a light emitting diode package according to the present invention will be described.

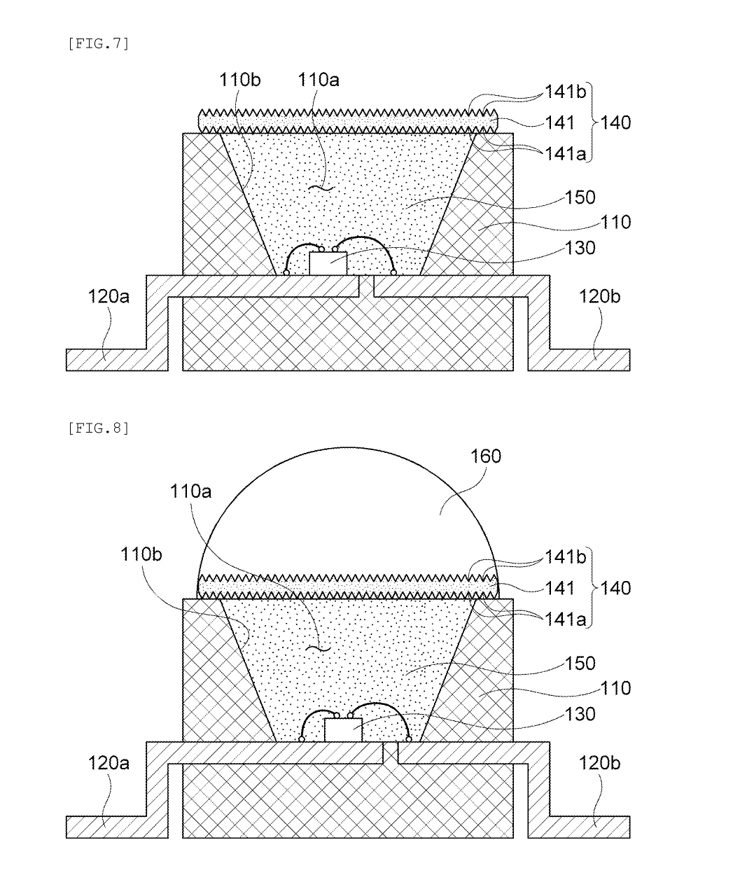

FIGS. 4 to 8 are cross-sectional views showing a manufacturing method of a light emitting diode package according to an exemplary embodiment of the present invention.

As shown in FIG. 4, a light emitting diode chip 130 is mounted on the bottom of an opening portion 110a of a package body 110.

Herein, the light emitting diode chip 130 is electrically mounted and fixed onto a first lead frame 120a positioned on the bottom of the opening portion 110a and the light emitting diode chip 130 is electrically connected with a second lead frame 120b through a wire.

Next, as shown in FIG. 5, a sheet 140 with an anti-reflecting unit 141 formed in moth-eye patterns 141a and 141b is formed.

Herein, the moth-eye patterns 141a and 141b may be formed by a plurality of protrusions having a nano size and the plurality of protrusions may have a cone shape.

In addition, the moth-eye patterns 141a and 141b have a nano structure (for example, a structure of 200 nm or less) of tens nanometers to hundreds nanometers or micrometers scale to reduce reflectivity on an interface.

The moth-eye effect is more effective in a pattern of a size smaller than a wavelength range of light reflectivity on the interface is rapidly reduced by consecutively changing refractivity of light incident in and the moth-eye pattern, that is, the plurality of protrusions having the nano size to remarkably improve light permeability.

Meanwhile, the sheet 140 may be formed by the fluorescent sheet manufactured by using a fluorescent substance as a main component, more specifically, may be manufactured by using a silicon material containing the fluorescent particles.

In this case, the sheet 140 with the anti-reflecting unit 141 formed in the moth-eye patterns 141a and 141b may be formed by using an imprint method of pressing the sheet 140 with two stamps 50.

Besides the above method, as shown in FIG. 6, the anti-reflecting unit 141 formed in the moth-eye pattern may be formed by applying a resin layer 141_1 to the sheet 140, and pressing and hardening the resin layer 141_1 with two stamps 50. Herein, the resin layer 141_1 may be configured by any one resin layer of a thermosetting resin or a UV cured resin.

In addition, as shown in FIG. 7, the sheet 140 is installed on the top of the opening portion 110a of the package body 110 and as shown in FIG. 8, the opening portion 110a of the package body 110 may be covered with a convex lens 160.

As set forth above, according to the exemplary embodiments of the present invention, a light emitting diode package and a manufacturing method thereof can improve light emitting efficiency of the light emitting diode package by implementing a fluorescent sheet that can serve to prevent reflection of light as well as emit light absorbed from a light emitting diode chip to the outside.

More specifically, it is possible to improve light permeability by reducing reflection of light by implementing a fluorescent sheet with an anti-reflecting unit formed in a moth-eye pattern on one surface or both surfaces.

As a result, reliability of the light emitting diode package can be improved.

While the present invention has been shown and described in connection with the exemplary embodiments, it will be apparent to those skilled in the art that modification and variation can be made without departing from the spirit and scope of the invention as defined by the appended claims.

What is claimed is:

1. A light emitting diode package, comprising:
a package body with an opening portion;
a light emitting diode chip mounted on the bottom of the opening portion; and
a sheet installed on the top of the opening portion and including an anti-reflecting unit formed in a moth-eye pattern.

2. The light emitting diode package according to claim 1, wherein the moth-eye pattern has a plurality of protrusions.

3. The light emitting diode package according to claim 2, wherein the plurality of protrusions have a cone shape.

4. The light emitting diode package according to claim 1, wherein the moth-eye pattern is formed in a nano size.

5. The light emitting diode package according to claim 1, wherein the sheet is made of a silicon material.

6. The light emitting diode package according to claim 1, wherein the sheet is a fluorescent sheet containing fluorescent particles.

7. The light emitting diode package according to claim 1, wherein a predetermined medium is received between the light emitting diode chip and the sheet.

8. The light emitting diode package according to claim 7, wherein the predetermined medium is configured by air.

9. The light emitting diode package according to claim 7, wherein the predetermined medium is configured by silicon.

10. The light emitting diode package according to claim 1, wherein in the package body, a side wall is formed on the circumference of the opening portion and the side wall is inclined toward the top from the bottom.

11. The light emitting diode package according to claim 10, wherein the side wall is applied with a metal thin film to reflect light emitted from the light emitting diode chip.

12. The light emitting diode package according to claim 1, wherein the anti-reflecting unit is formed on one surface or both surfaces of the sheet.

13. The light emitting diode package according to claim 1, wherein the sheet has the anti-reflecting unit formed in the moth-eye pattern by using an imprint method through a stamp.

14. The light emitting diode package according to claim 1, further comprising a convex lens covering the opening portion.

15. The light emitting diode package according to claim 1, further comprising:
first and second lead frames mounted on the package body to expose the bottom of the opening portion,
wherein the light emitting diode chip is electrically connected to each of the first and second lead frames.

16. A manufacturing method of a light emitting diode package, comprising:
mounting a light emitting diode chip on the bottom of an opening portion of a package body;
fabricating a sheet with an anti-reflecting unit formed in a moth-eye pattern; and
installing the sheet on the top of the opening portion.

17. The manufacturing method of a light emitting diode package according to claim 16, wherein in the fabricating of the sheet, the sheet with the anti-reflecting unit formed in the moth-eye pattern is fabricated by using an imprint method through a stamp.

18. The manufacturing method of a light emitting diode package according to claim 16, wherein the moth-eye pattern has a plurality of protrusions and the plurality of protrusions have a cone shape.

19. The manufacturing method of a light emitting diode package according to claim 16, wherein the anti-reflecting unit is formed on one surface or both surfaces of the sheet.

20. The manufacturing method of a light emitting diode package according to claim 16, wherein the fabricating of the sheet includes:
applying a resin layer to the sheet;
forming the anti-reflecting unit formed in the moth-eye pattern on the resin layer; and
hardening the resin layer with the anti-reflecting unit formed in the moth-eye pattern.

21. The manufacturing method of a light emitting diode package according to claim 16, further comprising covering the opening portion with a convex lens.
